(19) United States
(12) Patent Application Publication
(10) Pub. No.: US 2004/0104756 A1
(43) Pub. Date: Jun. 3, 2004

(54) Voltage level shifter circuit having high speed and low switching power

(76) Inventor: James E. Payne, Boulder Creek, CA (US)

Correspondence Address: SCHNECK & SCHNECK, P.O. BOX 2-E, SAN JOSE, CA, 95109-0005, US

(21) Appl. No.: 10/309,495

(22) Filed: Dec. 3, 2002

(51) Int. Cl. H03L 5/00

(52) U.S. Cl. 327/333

(57) ABSTRACT

A voltage level shifter comprises a plurality of PMOS transistors coupled in series with NMOS transistors to form a plurality of pull-down inverters. When the second voltage level is enabled to connect, the pull-down inverters pull down faster than the pull-down NMOS transistors alone, and thus, the pull-up PMOS transistors pull up immediately to connect the first voltage level to the second voltage level. Thus, the PMOS transistors added to form pull-down inverters improve the switching time and eliminate the kinks in the output voltage.

### TECHNICAL FIELD

The invention relates to a level shifter electronic circuit.

### BACKGROUND ART

It is often necessary to change from a small signal to a large signal in an integrated circuit. For example, transistors driven at two to three volts (2-3 volts) often interface with CMOS circuits that must be driven at 5 volts. Different logic families often interface to each other because there are situations when circuits must mix logic types. For example, many desirable LSI chips are built with NMOS, which has TTL-like output level around 3 volts that cannot directly drive a CMOS circuit. All CMOS families swing their outputs rail-to-rail. That means TTL output level cannot drive CMOS circuit families. In another example, memory circuits need to convert internal supply voltages Vcc to programming voltages. For example, in flash memory circuits, the programming voltage required to perform a page erase is 9 volts, while the Vcc is only 5 volts.

When interconnected circuit stages are not compatible, significant power loss results and the whole combination of stages often does not even operate. A level shifter circuit forms an interface between circuits having different operating voltages so that these circuits maintain same speeds and zero power consumption. Therefore, it is important to have a level shifter circuit to connect different circuit stages together without problems. One of the common circuit that has such a combination is the wordline driver.

With reference to FIG. 1, a wordline driver circuit 100 with a half-latch voltage level shifter 114 is illustrated. The wordline driver circuit 100 comprises a vmrow line 102 carrying a high erase voltage, an xpass line 104 for passing a CMOS voltage of 5 volts through the driver 100, a CMOS NAND logic gate 106, a first CMOS inverter 108, a second CMOS inverter 110, a zero threshold MOS transistor 112, the half-latch voltage level shifter 114, and a third CMOS inverter 116. The NAND gate 106 has a first input terminal rq and a second input terminal p. Both input terminals are 5 volts, while the vmrow line 102 is 9 volts. When the xpass terminal 104 is HIGH, the transistor 112 allows the voltage at rq terminal and q terminal of the NAND gate to pass through. Therefore, when the input of the inverter 116 is HIGH, the NMOS pull down is ON, the inverter 116 pulls the vmrow 102 to an electrical ground 118. When the input to the inverter 116 is LOW, the inverter 116 is ON, connecting the vmrow 102 to the wordline (wl) output terminal. Thus, the wl terminal is pulled up to the vmrow voltage of 9 volts via the voltage level shifter 114.

Wordline driver uses a p channel transistor driver and an n channel transistor driver; it needs a way to get output up to pump voltage so the p channel transistor does not shut off. This arrangement has a problem. When NMOS transistor pulls against the two PMOS transistors, it dumps current back through the circuit. It is necessary to pull all the way back up for next reading access.

FIG. 2 shows the manner the half-latch voltage shifter 114 operates to switch a CMOS voltage to a programming voltage. The half-latch voltage level shifter 114 includes two operation cycles. One cycle is for ON voltage, the other for OFF voltage. When the input to the wl line is HIGH, the half-latch voltage level shifter pulls the vmrow line down to ground voltage. In the other cycle, when the wl line is LOW, a transistor in the voltage level shifter is ON, connecting the vmrow line to the wl line. The half-latch voltage level shifter comprises an NMOS transistor 208 coupled to two PMOS transistors 204 and 206 for matching different voltage levels between a vmrow terminal 202 and the wl line 210. Usually, the voltage of the vmrow line 202 is the programming voltage, whereas the voltage of the wl terminal 210 is between 2 to 3 volts.

At first when wl line 210 is at zero voltage, the NMOS transistor 208 is cutoff and the PMOS transistor 206 is ON. As a result, the voltage at node A is pulled up to vmrow voltage. The regenerative feedback transistor 204 is OFF, isolating the wl line 210 to the vmrow 202 line. Next, when wl 210 is 5 volts, the NMOS transistor 208 pulls voltage at node A to ground voltage 212. When Va is nearly at ground voltage, the regenerative feedback PMOS transistor 204 is ON, connecting the vmrow terminal 202 to the wl terminal 210. While this happens, the PMOS transistor 206 is cutoff.

But when wl terminal 210 is transitioned back to 0 volt, the NMOS transistor 208 is cutoff and the PMOS transistor 206 is turned ON, pulling up node A to the vmrow voltage. Ideally, at the same time the PMOS transistor 204 should be turned OFF, isolating the vmrow line 202 from the wl line 210. Thus, ideally, the half-latch voltage level shifter 200 match the vmrow voltage 202 and wl voltage at node A without causing mismatching and current flow inside the circuit 200. However, in reality, the PMOS transistor 206 is not turned OFF at the same time as the PMOS 204 is ON. In a short period of time, both PMOS transistors 204 and 206 are ON and the pull-down NMOS transistor 208 cannot pull against the two PMOS transistors. This causes a short confusion state in the circuit. The confusion state causes current to flow to ground and creating kinks in the transient responses. Kinks in the current curve also cause power consumption.

In practice, the voltage level shifter 200 is used in many stages coupled by a gating network as disclosed in the U.S. Pat. No. 4,080,539 entitled “Level Shift Circuit” issued to RCA Corporation (“hereinafter” the '539 patent’). This patent discloses a half-latch circuit 10 coupled to another half-latch circuit 12 via a gating means 14 comprising two n-channel MOS transistors N2 and N3 coupled in parallel. The '539 patent also discloses another version of the level shifter circuit, which is the full-latch circuit as shown in FIG. 5 of the '539 patent. The full-latch circuit on the '539 patent is described below.

Referring to FIG. 3, a full-latch circuit uses two NMOS transistors. However, the prior art circuit in the '539 patent still has the kink problem. In the full-latch circuit, the kink current discussed above still flows before bitA gets up to Vm because an NMOS transistor cannot pull down fast enough against the PMOS transistors to avoid the confusion state discussed above.

Referring to FIG. 4, the kink in the graph 404 consumes power in the circuit. Graph 402 illustrates the output of the input inverter 306; and graph 404 illustrates the output of the inverter 308. Graph 406 shows the kinks caused by the current flowing from the first voltage level 304 to ground. This kink current is caused by the pull-down NMOS transistors 310 and 312 cannot switch fast enough against the pull up PMOS transistors.

The kinks in graph 400 in the responses of the circuit 300 causes current to flow and thus increases power consumption.

Therefore, there is a need to have a voltage power shifter that produces a smooth steady state voltage response so that it has zero power consumption and high switching speed.

### SUMMARY OF THE INVENTION

The above objects have been achieved by a voltage level shifter comprises a plurality of pull-up PMOS transistors coupled to pull-down NMOS transistors to form a plurality of pull-down inverters. These inverters have much better switching speed than a single pull down NMOS transistors. These inverters are coupled with pull-up PMOS transistors so that when the input voltage level switches, the pull-down inverters turn LOW more quickly than pull-down NMOS transistors alone. Consequently, the pull-up PMOS transistors turn ON faster. When the second voltage source of the input terminal is HIGH, one of the pull-down inverters pull low and thus a PMOS transistor is turned ON and connecting the first voltage source to the second voltage source. When the second voltage source is LOW, other pull-down inverters immediately go HIGH without any delay. Thus, the confusion states between pull-up PMOS transistors and pull-down NMOS transistors are avoided. As a result, the kinks are eliminated.

### BRIEF DESCRIPTION OF THE DRAWINGS

FIG. 1 illustrates the block diagram of a wordline driver that uses the half-latch to shift up the voltage.

FIG. 2 illustrates the schematic diagram of a prior art half-latch voltage level shifter used in the wordline driver described FIG. 1.

FIG. 3 illustrates a schematic diagram of a prior art full-latch voltage level shifter.

FIG. 4 illustrates a graph of the voltage responses of the prior art full-latch voltage level shifter of FIG. 3.

FIG. 5 illustrates a schematic diagram of a full-latch voltage level shifter according to the present invention.

FIG. 6 illustrates a graph of the voltage responses of the full-latch voltage level shifter described in FIG. 5 according to the present invention.

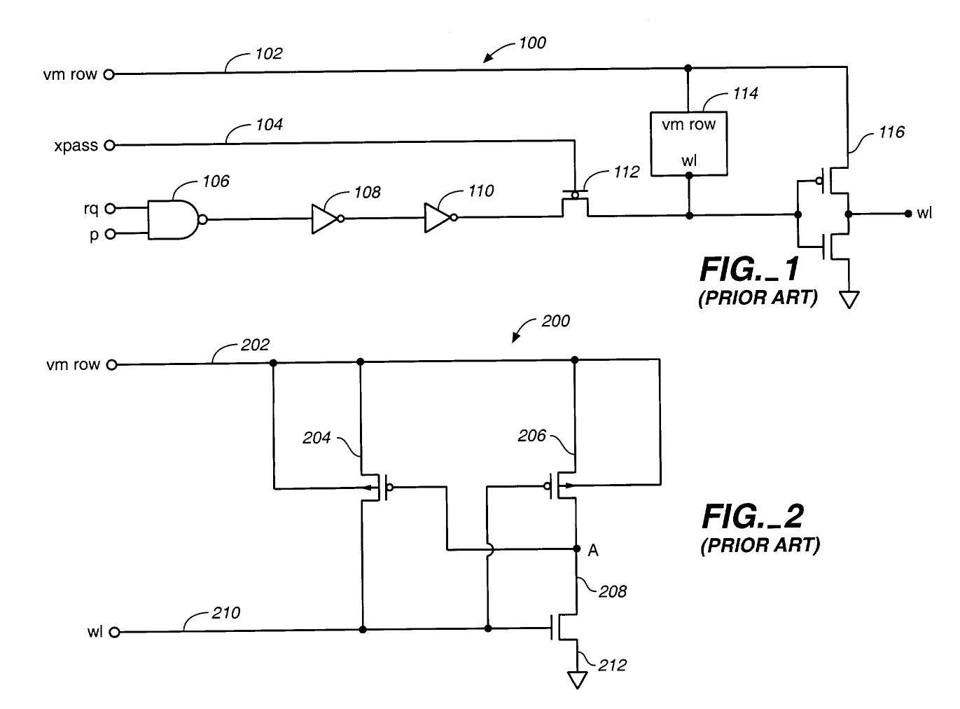

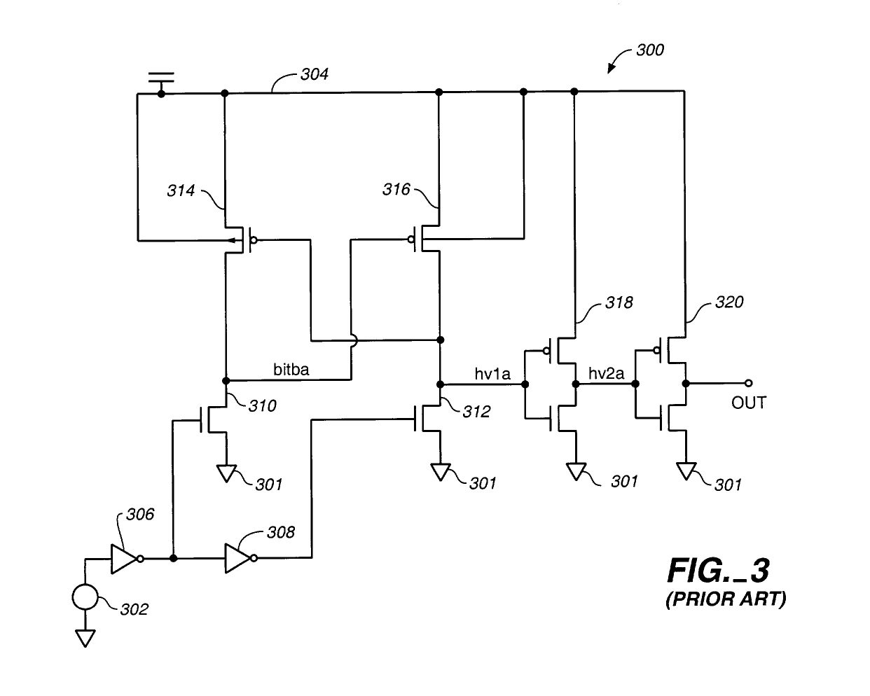

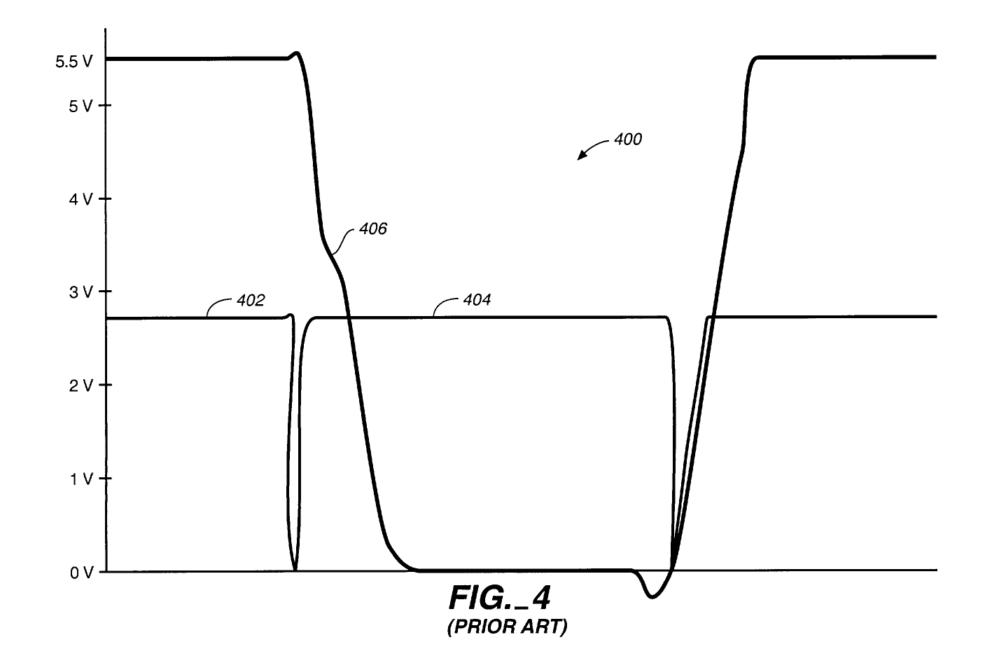

### DETAILED DESCRIPTION OF THE PREFERRED EMBODIMENT

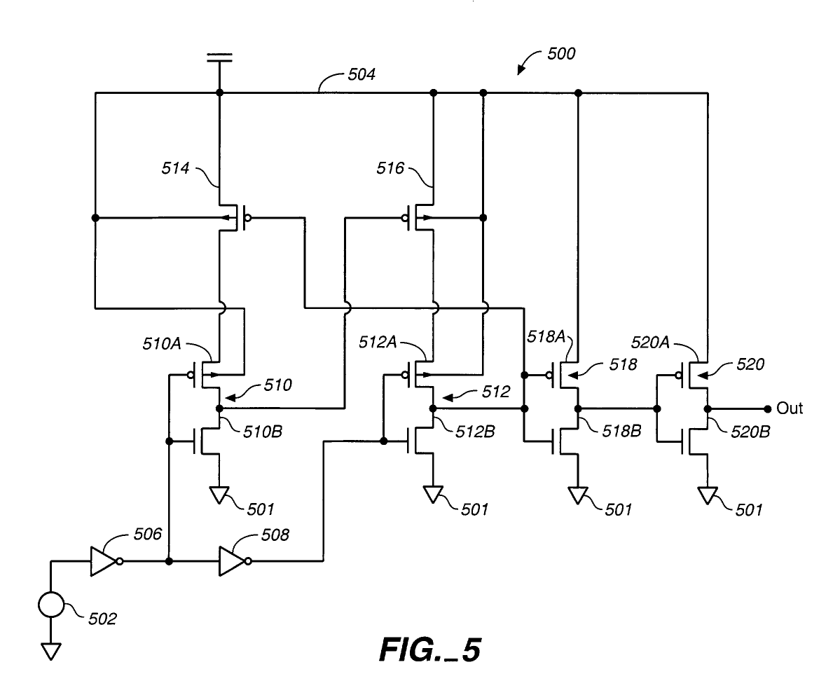

In reference to FIG. 5, a voltage level shifter 500 comprises a plurality of NMOS and PMOS transistors coupled together to form pull-down inverters. The pull-down inverters are coupled to pull-up PMOS transistors so that the switching time of the voltage level shifter is significantly improved because the pull-down inverters pull down immediately and turn on the pull-up PMOS transistors faster than pull-down NMOS transistors alone. This eliminates the confusion states between pull-up PMOS transistors and pull-down NMOS transistors that causes unwanted current to flow from the first voltage level to ground.

The voltage level shifter 500 comprises a first PMOS transistor 514 and a second PMOS transistor 516 coupled to a first voltage level 504. The voltage level shifter 500 also has additional PMOS transistors such as a third PMOS transistor 510A and a fourth PMOS transistor 512A. The body of the third PMOS transistor 510A is coupled to the body of the first PMOS transistor 514 and to the first voltage level 504. The body of the fourth PMOS transistor 512A is coupled to the body of the second PMOS transistor 516 and to the first voltage level 504. The drain of the third PMOS transistor 510A is coupled to the source of the first PMOS transistor 514 and the drain of the fourth PMOS transistor 512A is coupled to the source of the second PMOS transistor 516. The voltage level shifter 500 further includes a first NMOS transistor 510B and a second NMOS transistor 512B.

The third PMOS transistor 510A and the first NMOS transistor 510B are coupled to form a first pull-down inverter 510. More particularly, the drain of the first NMOS transistor 510B is coupled to the source of the third PMOS transistor 510A and to the gate of the second PMOS transistor 516. The gate of the first NMOS transistor 510B is coupled to the gate of the third PMOS transistor 510A. The source of the first NMOS transistor 510 is coupled to an electrical ground 501.

The fourth PMOS transistor 512A and the second NMOS transistor 512B are coupled to form a second pull-down inverter 512. The drain of the second NMOS transistor 512B is coupled to the source of the fourth PMOS transistor 512A, and the gate of the second NMOS transistor 512B is coupled to the gate of the fourth PMOS transistor 512A. The source of the second NMOS transistor is coupled to the electrical ground 501. Thus, each pull-up PMOS transistor 514 and 516 is coupled in series to one of the inverters 510 and 512 formed, respectively, by the pair 510A, 510B and the pair 512A and 512B.

The voltage level shifter 500 comprises an input stage, which includes a first input inverter 506 and a second input inverter 508. Each input inverter has an input terminal and an output terminal. The input terminal of the first input inverter 506 is coupled to a second voltage level 502. The output of the first input inverter 506 is coupled to the gate of the first NMOS transistor 510B and to the input of the second input inverter 508. The output of the second input inverter 508 is coupled to the gate of the second NMOS transistor 512B.

Finally, voltage level shifter 500 also has an output stage, which includes a first output inverter 518, a second output inverter 520. The first output inverter 518 further comprising a fifth PMOS transistor 518A and a third NMOS transistor 518B. The second output inverter 520 has a sixth PMOS transistor 520A and a fourth NMOS transistor 520B. These output inverters 518 and 520 are coupled in series. The input of the first output inverter is coupled to the drain-source of the fourth PMOS transistor 512A and the second NMOS transistor 512B, and to the gate of the first PMOS transistor 514. The output of the first output inverter 518 is coupled to the input of the second output inverter 520. The drain of the fifth PMOS transistor 518A of the first output inverter 518 is coupled to the first voltage level 504.

The drain of the sixth PMOS transistor 520A is coupled to the first voltage level 504 and the output forms the overall output of level shifting circuit.

When the second voltage level 502 is ON, the second pull-down inverter 512 formed by the pair 512A and 512B outputs a LOW voltage because the second NMOS transistor 512B is ON, pulling its output to LOW. Therefore, the first PMOS pull-up transistor 514 is ON. In the meantime, the output of the first input inverter 506 is HIGH, pulling the output of the first pull-down inverter 510 formed by the transistor pair 510A and 510B up to the first voltage level. As such, the drain-source terminal of the PMOS transistor buffer 522 is pulled up to the first voltage level.

When the second input voltage level 502 switches to LOW, the output of the inverter 510 is LOW, quickly turning ON the second PMOS pull-up transistor 516. Therefore, the drain-source terminal of the pull-up PMOS transistor 516 and PMOS transistor 512A becomes LOW. The pull-down inverters 510 and 512 help the voltage level shifter 500 to switch faster, avoiding the confusion state when both the PMOS transistors 514 and 516 are HIGH because the pull-down NMOS transistors 510B and 512B cannot switch and pull-down the PMOS transistors fast enough. Because the inverters 510 and 512A pull down faster, and thus the PMOS transistors 514-516 pull up faster, there is not leakage current and no kinks in the curve.

In summary, when the second voltage level 502 is ON, the inverter 512 quickly goes LOW, causing the first PMOS pull-up transistor 514 to pull up to the first voltage level. This causes the output at the drain source terminal of the PMOS buffer 522 to goes HIGH. In this situation, the first PMOS transistor 514 and the third PMOS transistor 510A are ON, the second NMOS transistor 512B is also ON, while the second PMOS transistor 516 and the fourth PMOS transistor 512A are OFF. When the second voltage level 502 switches LOW, the opposite happens. In particular, the second PMOS transistor 516, the fourth PMOS transistor 512A are ON, while the transistors 514 and 510A are OFF.

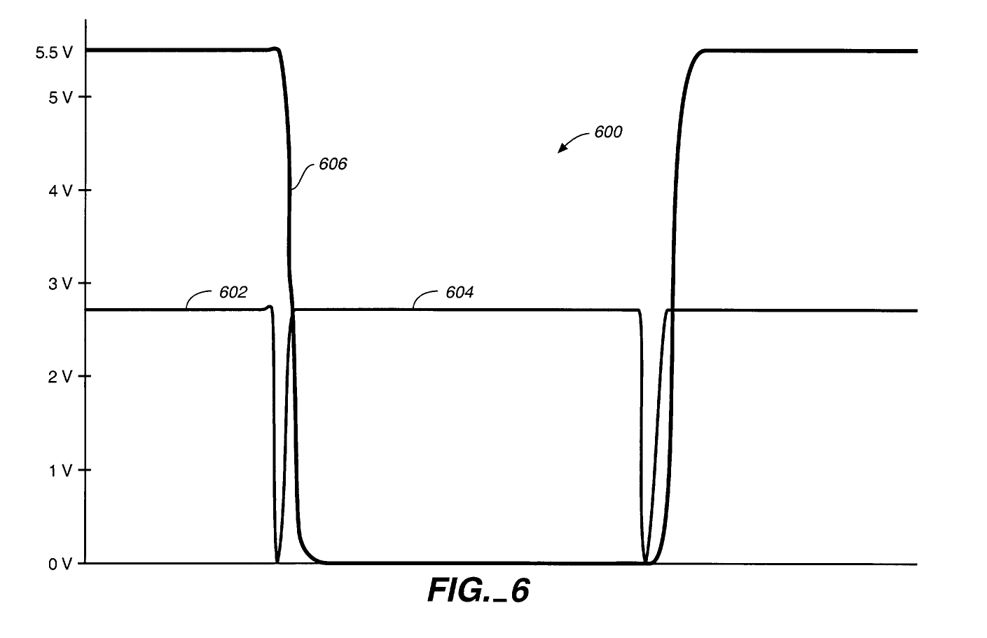

The fast switching time of the pair of inverters 510 and 512 quickly turns the pull-up PMOS transistor 514 and 516 ON and OFF. This improves the switching time of the voltage level shifter 500, and thus eliminates the kink in the voltage response as shown in FIG. 6.

In reference to FIG. 6, graph 6 show the input and output of the voltage level shifter 500. Graph 602 illustrates the voltage response of the second voltage level 502. Graph 604 illustrates the voltages response at the output of the first input inverter 506. Graph 606 illustrates the voltage response of the output terminal of the voltage level shifter 500. The voltage response 606 is without the kinks because the pull-down inverters 510 and 512 help pull down faster and thus the pull-up PMOS transistors 514 and 516 to pull up faster. This fast switching time eliminates unwanted current to flow from the first voltage level 504 to ground. And, thus, eliminates the kinks as shown in graph 606.

What is claimed is:

1. A voltage level shifter circuit, comprising:
(a) a plurality of PMOS pull-up transistors, each having a drain terminal coupled to a first voltage level;
(b) a plurality of pull-down inverter means for improving a switching time of the voltage level shifter, wherein each pull-down inverter means is coupled in series with each of the plurality of pull-up transistors;
(c) an output buffer circuit coupled to the plurality of pull-down inverter means; and
(d) a plurality of input inverters coupled to the plurality of pull-down inverter means and to a second voltage level.

2. The voltage level shifter of claim 1, wherein the each of the plurality of pull-down inverter means comprising an NMOS transistor coupled in series with a PMOS transistor, the gate of the NMOS transistor being coupled with the gate of the PMOS transistor to form an input terminal of the pull-down transistor means, the drain of the NMOS transistor coupled with the source of the PMOS transistor to form an output terminal of the pull-down transistor means, the source of the NMOS transistor being coupled to an electrical ground, and the body of the PMOS transistor being coupled to the first voltage level.

3. The voltage level shifter of claim 1, wherein each pull-up PMOS transistor comprises a drain terminal, a gate terminal, a source terminal, and a body terminal, and wherein the body terminal is coupled to the first voltage level, and the source terminal is coupled in series with the plurality of the pull-down inverter means.

4. The voltage level shifter of claim 1, wherein the output buffer circuit comprises a first inverter and a second inverter coupled in series; the first and second inverter, each having a PMOS transistor coupled in series with an NMOS inverter, each NMOS transistor and PMOS transistor having a drain, a gate, and a source, the drain of the PMOS transistor coupled to the first voltage level, the gate of the PMOS transistor coupled to the gate of the NMOS transistor to form an input terminal of the inverter, the source of the PMOS transistor is coupled to the drain of the NMOS transistor to form an output terminal, and the source of the NMOS transistor coupled to an electrical ground.

5. The voltage level shifter of claim 1, wherein the plurality of input inverters further comprises an inverter for each pull-down inverter means; each input inverter having an input terminal and an output terminal, the input terminal of a first input inverter is coupled to the second voltage level and the output terminal of a each inverter coupled to an input terminal of each pull-down inverter means.

6. A voltage level shifter circuit comprising:
(a) a first PMOS transistor and a second PMOS transistor coupled to a first voltage level, each having a drain, a gate, a source, and a body;
(b) a third PMOS transistor and a fourth PMOS transistor each having a drain, a gate, a source, and a body, wherein the body of the third transistor being coupled to the body of the first PMOS transistor and to the first voltage level, the body of the fourth PMOS transistor being coupled to the body of the second PMOS transistor and to the first voltage level, the drain of the third PMOS transistor being coupled to the source of the first PMOS transistor, the drain of the fourth PMOS transistor being coupled to the source of the second PMOS transistor;
(c) the first NMOS transistor and a second NMOS transistor, each having a gate, a drain, and a source, wherein the drain of the first NMOS transistor being coupled to the source of the third PMOS transistor and to the gate of the second PMOS transistor, the gate of the first NMOS transistor coupled to the gate of the third PMOS transistor, the drain of the second NMOS transistor being coupled to the source of the fourth PMOS transistor, the gate of the second NMOS transistor coupled to the gate of the fourth PMOS transistor;
(d) a first inverter and a second inverter, each having an input terminal and an output terminal, wherein the input terminal of the first inverter being coupled to a second voltage level, the output of the first inverter being coupled to the gate of the first NMOS transistor and to the input of the second inverter, the output of the second inverter coupled to the gate of the second NMOS transistor;
(e) a first output inverter and a second output inverter, wherein the first output inverter further comprising a fifth PMOS transistor and a third NMOS transistor, the second output inverter having a sixth PMOS transistor and a fourth NMOS transistor, each transistor having a drain, a gate, and a source; the gates of the fifth PMOS transistor and the third NMOS transistor coupled together and to the gate of the first PMOS transistor, the drain of the fifth PMOS transistor coupled to the first voltage level, the source of the fifth PMOS transistor coupled to the drain of the third NMOS transistor, the source of the third transistor coupled to the electrical ground; the gates of the sixth PMOS transistor and the fourth NMOS transistor coupled together and to the source of the fifth PMOS transistor, the drain of the sixth PMOS transistor coupled to the first voltage level, the source of the sixth PMOS transistor coupled to the drain of the fourth NMOS transistor, and the source of the fourth NMOS transistor coupled to the electrical ground.
